(19) United States
(12) Patent Application Publication
(10) Pub. No.: US 2016/0204425 A1
(43) Pub. Date: Jul. 14, 2016

(54) Facile Preparation Method of Silicon Materials for LI-Ion and Solar Cell Application

(71) Applicants: Alexey Serov, Albuquerque, NM (US); Plamen B Atanassov, Santa Fe, NM (US)

(72) Inventors: Alexey Serov, Albuquerque, NM (US); Plamen B Atanassov, Santa Fe, NM (US)

(73) Assignee: STC.UNM, Albuquerque, NM (US)

(21) Appl. No.: 14/915,581

(22) PCT Filed: Aug. 27, 2014
(86) PCT No.: PCT/US14/52849

§ 371 Date: Feb. 29, 2016

Related U.S. Application Data
(60) Provisional application No. 61/871,487, filed on Aug. 29, 2013.

(51) Int. Cl. H01M 4/36; H01L 31/0376; H01M 4/587; H01M 4/48; H01M 10/0525; H01L 31/20; H01M 4/38

(52) U.S. Cl. CPC H01M 4/366; H01L 31/202; H01L 31/03762; H01M 4/386; H01M 4/364; H01M 4/483; H01M 10/0525; H01M 4/587; H01M 2004/027

(57) ABSTRACT

According to various embodiment the present disclosure provides novel and inexpensive methods of forming amorphous silicon and silicon composite materials with specific pre-determined morphologies and oxygen contents. The various forms of amorphous silicon that result from these methods is useful in a wide variety of applications including, but not limited to, solar and lithium-ion batteries.

### CROSS-REFERENCE TO RELATED APPLICATIONS

The following application claims benefit of U.S. Provisional Application No. 61/871,487, filed Aug. 29, 2013, which is hereby incorporated by reference in its entirety.

### BACKGROUND

Lithium-ion and solar batteries present great opportunities for energy storage and are of great interest for a wide variety of both household, commercial, and industrial uses. Solar batteries are of great interest due to their environmentally friendly nature while the high density, low weight and small size of Li-ion batteries makes these storage devices highly desirable for mobile and other small-sized devices.

Silicon materials are widely used in solar batteries and have received recent attention for use in Li-ion batteries. In solar batteries, silicon is typically used as the matrix in which semiconductors are embedded and in Li-ion batteries, silicon is being used as an anode material. In both cases, performance is improved through the use of highly specific silicon morphology. In both cases, there is a need to balance stability and cycle performance with manufacturing and operational costs. For example, in traditional solar cell technology there has been a long-standing debate between the use of monocrystalline cells, which require the production of silicon ingots, a difficult and expensive process, and amorphous silicon, which is less expensive to manufacture than silicon ingots, but which degrades more easily. In Li-ion technology, silicon anodes have shown increased stability of the standard carbon anodes, but silicon anodes have shown diminished cycle performance.

One method for balancing cycle performance and stability in Li-ion batteries is to use silicon carbon composites. These anodes typically have higher charge capacity than silicon-only anodes, but can be expensive and time-consuming to produce, as they have typically required a two-step procedure wherein the silicon is first produced and then the carbon layered or added onto the silicon.

Furthermore, the performance of both solar and Li-ion batteries is also affected by the oxygen content in the silicon materials, though in different ways. In solar batteries it is desirable to have very low oxygen content while in Li-ion batteries oxygen content needs to be balanced with lithium usage.

Accordingly, it will be appreciated that various industries would benefit greatly from the development of inexpensive methods of manufacturing amorphous silicon and silicon composite materials that enable the production of materials with specific pre-determined morphologies and oxygen contents.

### SUMMARY

The present disclosure provides novel methods of forming amorphous silicon and silicon composite materials with specific, pre-determined, morphologies and oxygen contents.

### BRIEF DESCRIPTION OF THE DRAWINGS

FIG. 1 is a flow chart showing a method for forming amorphous silicon according to an embodiment of the present disclosure.

FIG. 2A is a schematic illustration of a mixture of silica and reductive metal resulting from a higher amount of silica relative to reductive metal combined with a longer ball-milling time and higher heat treatment temperature profile.

FIG. 2B is a schematic illustration of the material that results from the removal of the metal oxide from the mixture shown in FIG. 2A.

FIG. 3A is a schematic illustration of a mixture of silica and reductive metal resulting from a lower amount of silica relative to reductive metal combined with a shorter ball-milling time and lower heat treatment temperature profile.

FIG. 3B is a schematic illustration of the material that results from the removal of the metal oxide from the mixture shown in FIG. 3A.

FIG. 4 is a flow chart showing a method for forming supported amorphous silicon according to an embodiment of the present disclosure.

FIG. 5 is a flow chart showing another method for forming supported amorphous silicon according to an embodiment of the present disclosure.

FIG. 6 is a scanning electron microscope (SEM) images of the surface of amorphous silicon formed using the method described herein.

FIG. 7 is an SEM image of the surface of silicon formed with low surface area silica.

FIG. 8 is an SEM image of the surface of Si/C composite formed from high surface area silica.

FIG. 9 is an SEM image of the surface of Si/CNT composite formed from low surface area silica.

FIG. 10 is an SEM image of the surface of Si/CNT/graphene composite formed from low surface area silica.

FIG. 11 shows XRD data for amorphous silicon formed using the method described in the Experimental section.

FIG. 12 a scanning electron microscope (SEM) images of the surface of amorphous silicon formed using the method described herein.

FIG. 13 a scanning electron microscope (SEM) images of the surface of amorpohous silicon formed using the method described herein.

FIG. 14 is an SEM image of the surface of silicon formed with low surface area silica.

FIG. 15 is an SEM image of the surface of silicon formed with low surface area silica.

FIG. 16 shows data generated by composite materials formed with different amounts of carbon.

### DETAILED DESCRIPTION

According to various embodiment the present disclosure provides novel and inexpensive methods of forming amorphous silicon and silicon composite materials with specific pre-determined morphologies and oxygen contents. The various forms of amorphous silicon that result from these methods is useful in a wide variety of applications including, but not limited to, solar and lithium-ion batteries.

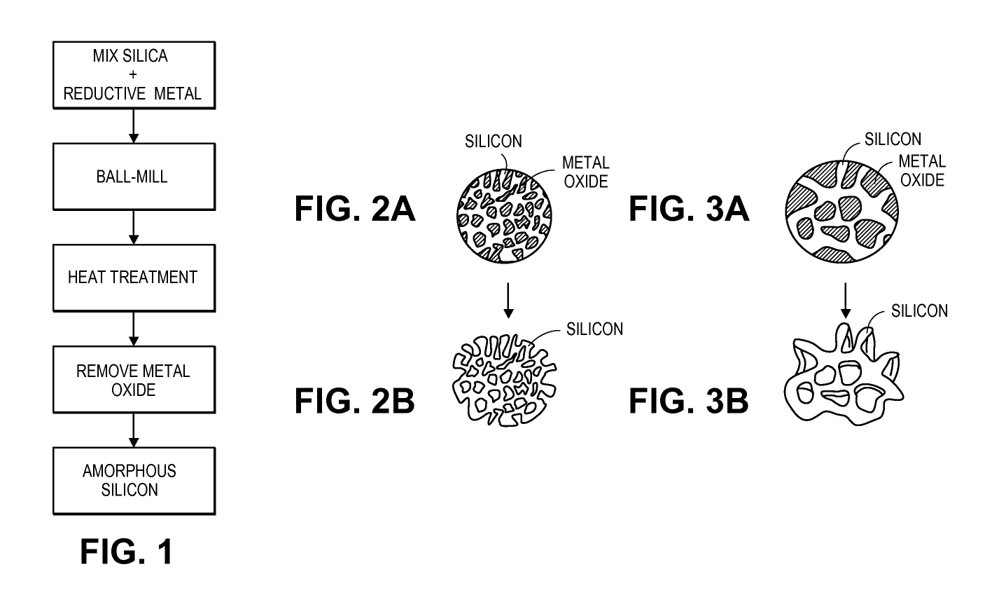

According to an embodiment, and as shown in FIG. 1, amorphous silicon is formed by ball-milling one or more silicon precursors in the presence of one or more reductive metals under sufficient conditions to initiate reduction of the silicon by the metal. Examples of suitable silicon precursors include, but are not limited to silicas such as silicon oxide and silicon dioxide, silanes, silosanes etc. Examples of suitable reductive metals include, but are not limited to magnesium, aluminum, calcium, sodium, potassium, lithium, and the like. For the purposes of the present disclosure a reductive metal is considered any metal that has a chemical reductive potential to oxygen that is higher than those of the silicon precursors.

For the purposes of the present disclosure, the term “ball mill” is used to refer to any type of grinder or mill that uses a grinding media such as silica abrasive or edged parts such as buns to grind materials into fine powders and/or introduce to the system enough energy to start a solid state chemical reaction. In general, for the purposes of the present disclosure, the ball mill used should be capable of producing enough energy to initiate the desired chemical reaction or achieve the desired level of mixing.

Those of skill in the art will realize that the RPM and timeframe for ball-milling will depend largely on the materials and equipment being used. However, as a general rule, we have found that ball-milling at an RPM of between 100 and 550 RPM for at least 0.5 hours and typically no more than 24 h hours is sufficient for the materials we have tested.

The mixture resulting from the ball-milling is then heat treated in an inert atmosphere, such as argon, hydrogen, or helium in order to produce a composite material containing silicon and metal oxide, as shown in FIGS. 2A and 3A. Again, it will be appreciated that the length of time and temperature of the heat treatment will be determined by the specific materials and equipment being used. For example, in general it is know that magnesium will react at 700° C., aluminum at 500° C., calcium at 300° C. and lithium, potassium, and sodium at room temperature. However, it should also be appreciated that temperature can be compensated for by increasing the energy of the ball mill

As desired, some or all of the metal oxide material can be easily removed by, for example, exposure to a mineral acid such as hydrochloric acid (HCl), nitric acid, H₂SO₄ etc. It should be noted that some silicon, metal oxide and acid combinations (such as Si+MgO+HCl) may result in a self-igniting by-product such as SiH₄ and suitable precaution should thus be taken. Other suitable acids include, but are not limited to, HNO₃ and H₂SO₄. Of course those of skill in the art will appreciate that the specific acid being used should be selected as one that is appropriate for removal of the metal oxide that is formed as determined by the selected initial reaction components.

As shown in FIGS. 2B and 3B, it will be appreciated that removal of the metal oxide material will produce a silicon material comprising a plurality of silicon crystallites and voids that exist where the metal oxide had originally resided in the silicon-metal oxide composite material. For the purposes of the present disclosure, the term “void” is used to refer to a space that is created by the removal of some or all of a material that had been in situ formed during the silicon precursor reduction.

According to various embodiments, the size and presence of both the crystallites and voids (and thus the resulting density, surface area, and overall morphology of the resulting silicon material) can be determined by a combination of: the initial ratio of silica to reductive metal, the ball-milling time, the heat treatment temperature profile and chemical environment. Specifically, as further demonstrated in the Experimental section below, a higher amount of silica relative to reductive metal combined with a longer ball-milling time and higher heat treatment temperature profile results in a denser silicon material (as shown in FIG. 2B), while a higher amount of reductive metal relative to silica, a shorter ball-milling time, and a lower heat treatment temperature results in a looser, results in a more open silicon framework (as shown in FIG. 3B). In addition to simply adding more or less silica to the initial reaction, this ratio can be also be affected by the type and surface area of the silica used. For example, as shown in the Experimental section below, the use of high surface area silica (commercially available from Cabot, Evonik etc) produced the denser more tightly packed silicon material, while the use of low surface area silica (commercially available from Cabot and Evonik resulted in a looser, more open silicon framework.

It will be appreciated that only the metal oxide that is accessible to the acid will be removed. Accordingly, if the resulting material has controllable density, the silicon material may contain an externally inaccessibly core that contains metal, metal oxide, and/or silica materials.

As stated above, according to some embodiments, it is desirable to produce materials having a predetermined oxygen content. Accordingly, the methods of the present disclosure provide a mechanism for controlling the oxygen content of the final product. According to an embodiment, the oxygen content can be controlled by selecting the specific reductive metal used in the reaction. For example, using Zn will result in a final product with higher oxygen content while using Mg will result in a final product with lower oxygen content.

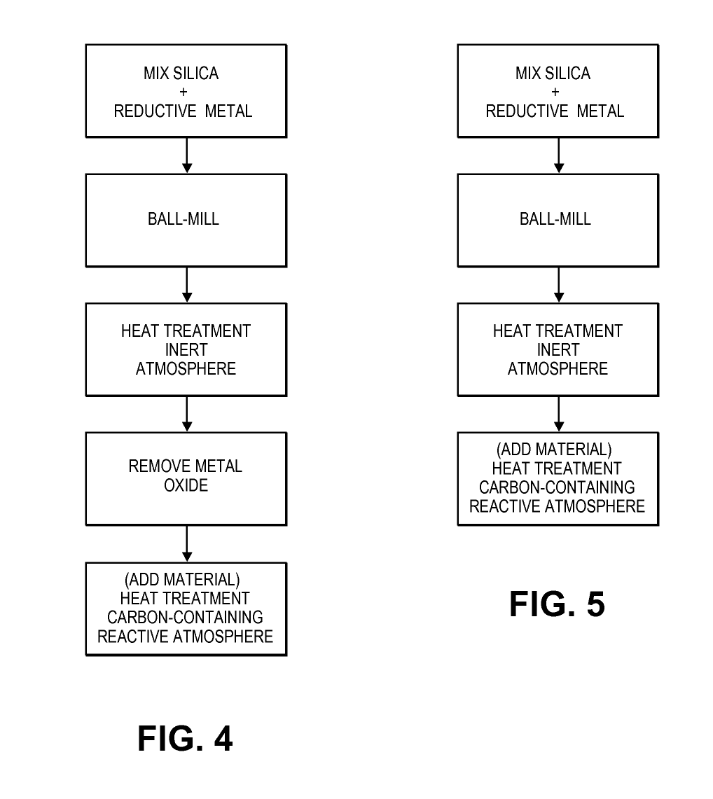

As also stated above, according to some embodiments it is desirable to produce a silicon-carbon composite material. According to some embodiments, and as shown in FIG. 4, the silicon materials produced above are heat treated in a reactive atmosphere such as ethylene (C₂H₄) or mixed with one or more precursors and then heat treated in a reactive atmosphere to produce a silicon carbon material. If desired, the silicon-carbon composite can then be ball-milled a second time. This second ball-milling step may be performed, for example, in those embodiments where it is desirable to obtain better integration of the materials, such as when the materials will be used in a Lithium battery. In other embodiments, it may not be necessary and thus can be omitted.

According to a first example, and as discussed in greater detail in the Experimental section below, the amorphous silicon produced using the above-described method may be heat treated in C₂H₄ to produce a silicon-carbon (Si/C) composite.

According to a second example, and as discussed in greater detail in the Experimental section below, the amorphous silica produced using the above-described method may be mixed with iron nitrate, graphite, graphene, and/or carbon and heat treated in C₂H₄ to produce a silicon-carbon nanotube (Si/CNT) composite.

According to a third example, and as discussed in greater detail in the Experimental section below, the amorphous silicon produced using the above-described method may be mixed with graphene oxide and iron nitrate and heat treated in C₂H₄ to produce a silicon-carbon nanotube-graphene (Si/CNT/graphene) composite.

According to another embodiment of forming a silicon-carbon composite, shown in FIG. 5, rather than performing two separate heat treatment steps, a reductive metal that will produce a volatile metal oxide, such as zinc, can be used in the initial reaction. The zinc (or other metal) and silica are ball milled and then are initially heat treated an inert atmosphere to produce silicon and zinc oxide, the heat treatment conditions are then switched to a reactive, carbon-containing atmosphere, for example by the introduction of C₂H₄, to produce the silica-carbon composite material. Any remaining zinc oxide (or other material) can then be removed, for example, by use of an acid wash. Suitable acids include, for example, HCl.

As stated above, the presently described methods may be used to produce a material suitable for use as a silicon or silicon-carbon composite anode for use in a Lithium-ion battery. The materials produced by the presently described methods are particularly well suited for this application as they can be used to produce low surface area silicon in the form of large particles with numerous small channels (formed by the removal of the metal oxide from the surface of the particles) which present the lithium ions to the current collector, even during the inevitable expansion and contraction of the silicon particle. Furthermore, it is noted that because lithium is, itself, a reductive metal, the silicon to be used in a lithium ion battery can be formed using lithium as one of the initial materials. In this embodiment, any remaining lithium oxide can be removed by washing with water prior to use.

The terms and expressions that have been employed are used as terms of description and not of limitation, and there is no intent in the use of such terms and expressions to exclude any equivalent of the features shown and described or portions thereof, but it is recognized that various modifications are possible within the scope of the invention as claimed. Thus, it will be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

All patents and publications referenced below and/or mentioned herein are indicative of the levels of skill of those skilled in the art to which the invention pertains, and each such referenced patent or publication is hereby incorporated by reference to the same extent as if it had been incorporated by reference in its entirety individually or set forth herein in its entirety. Applicants reserve the right to physically incorporate into this specification any and all materials and information from any such cited patents or publications.

### Experimental:

### 1. Formation of Silicon Material—High Surface Area Silica

217 g of high surface area silica was mixed with 321 g of magnesium powder. The mixture was ball-milled at 500 RPM for 24 hours. 125 g of prepared mixture was heat treated in argon atmosphere at T=750° C. for 3 h. As produced Si+MgO composite was placed into 1M solution of HCl (precaution: SiH₄ produced and self-ignited!). Silicon was filtrated and dried overnight at T=85° C.

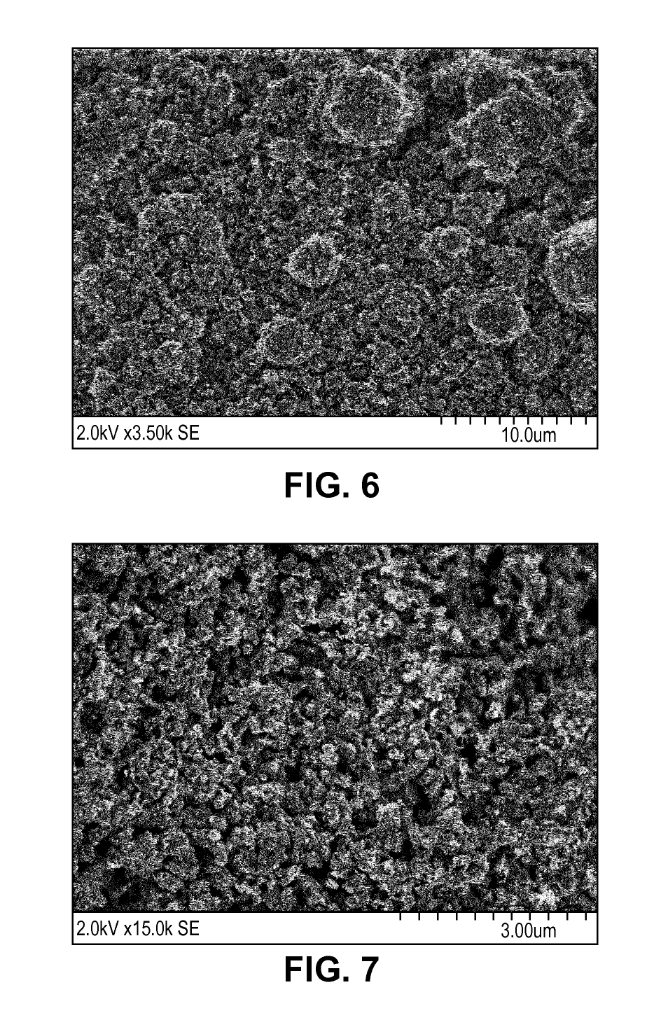

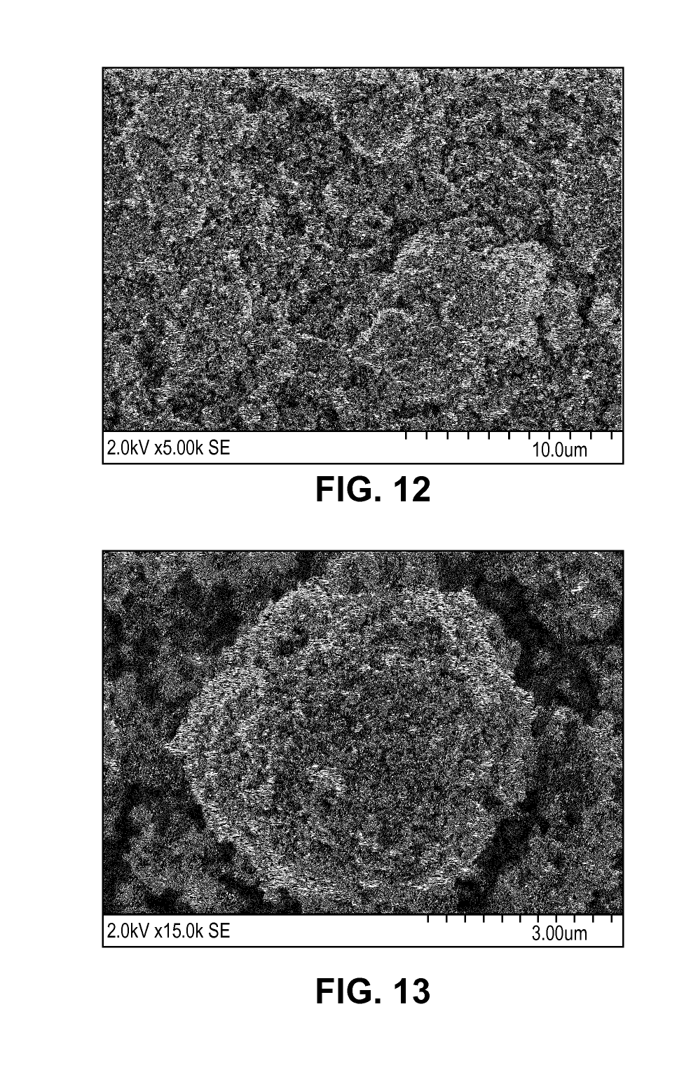

FIGS. 6, 12 and 13 are scanning electron microscope (SEM) images of the surface of silicon formed using this method.

FIG. 11 shows XRD data for silicon formed using this method.

### 2. Formation of Silicon Material—Low Surface Area Silica

118 g of low surface area silica was mixed with 201 g of magnesium powder. The mixture was ball-milled at 550 RPM for 5 hours. 95 g of prepared mixture was heat treated in argon atmosphere at T=650° C. for 4h. As produced Si+MgO composite was placed into 5M solution of HCl (precaution: SiH4 produced and self-ignited!). Silicon was filtrated and dried overnight at T=85° C.

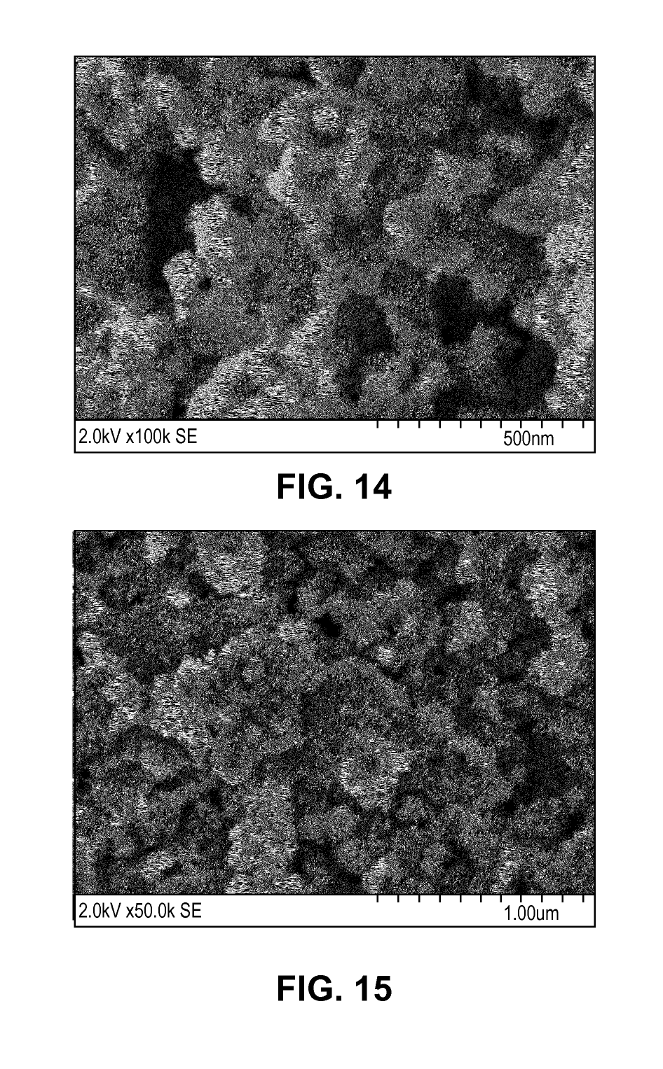

FIGS. 7, 14 and 15 are SEM images of the surface of silicon formed using this method.

### 3. Formation of Silicon-Carbon Composite Material

Silicon was formed as described above in 1 or 2 above and then 55 g of prepared silicon (methods mentioned above) were heat treated in C₂H₄ atmosphere for 2 hours at T=800° C. The obtained Si/C composite was ball-milled at 500 RPM for 2 hours.

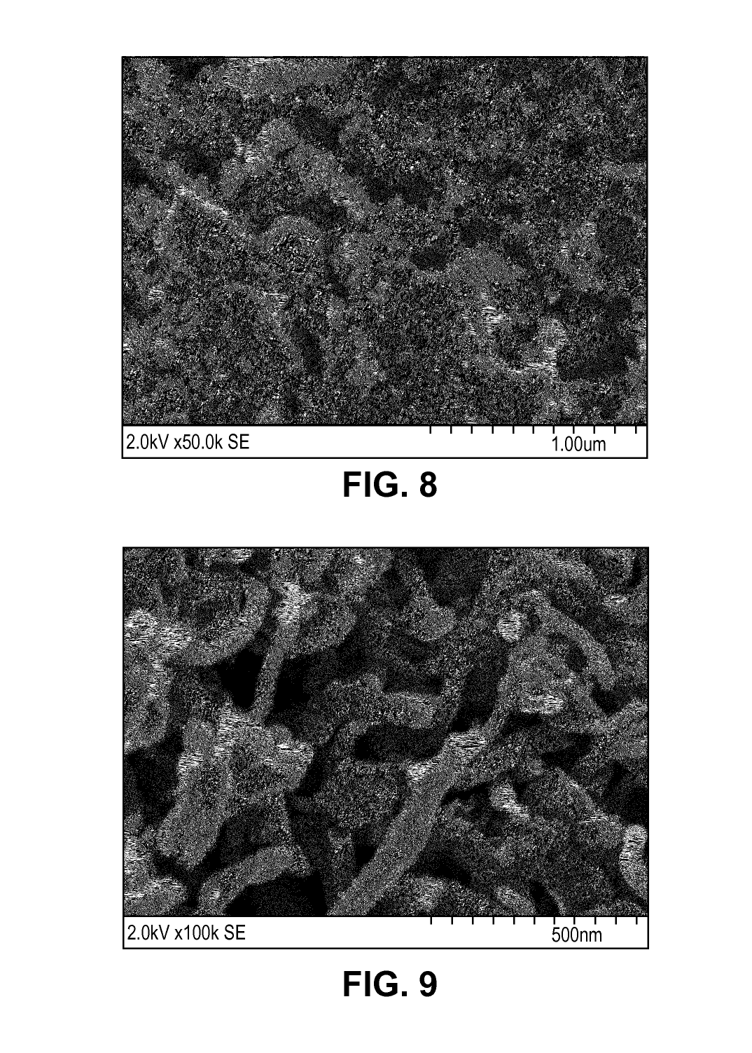

FIG. 8 is an SEM image of the surface of Si/C composite formed from high surface area silica.

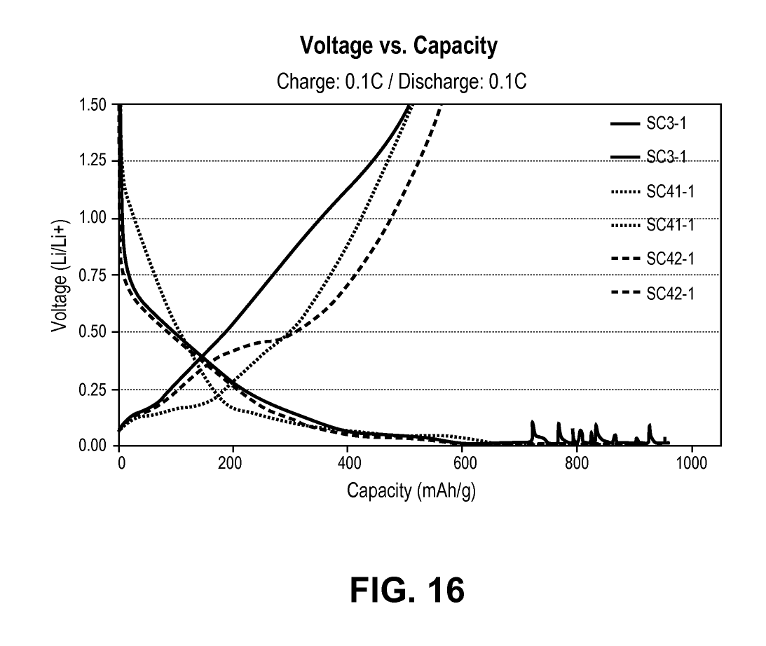

FIG. 16 shows data generated by composite materials formed with different amounts of carbon.

4. Formation of Silicon-CNT Composite Material

Silicon was formed as described above in 1 or 2 above and then 38 g of prepared silicon (methods mentioned above) were mixed with 5 g of iron nitrate and heat treated in C₂H₄ atmosphere for 2 hours at T=800° C. The obtained Si/CNT composite was ball-milled at 500 RPM for 2 hours.

FIG. 9 is an SEM image of the surface of Si/CNT composite formed from low surface area silica.

### 5. Formation of Silicon-CNT-Graphene Composite Material

Silicon was formed as described above in 1 or 2 above and then 25 g of prepared silicon (methods mentioned above) were mixed with 20 g of graphene oxide 5 g of iron nitrate heat treated in C₂H₄ atmosphere for 2 hours at T=800° C. The obtained Si/CNT/graphene composite was ball-milled at 500 RPM for 2 hours.

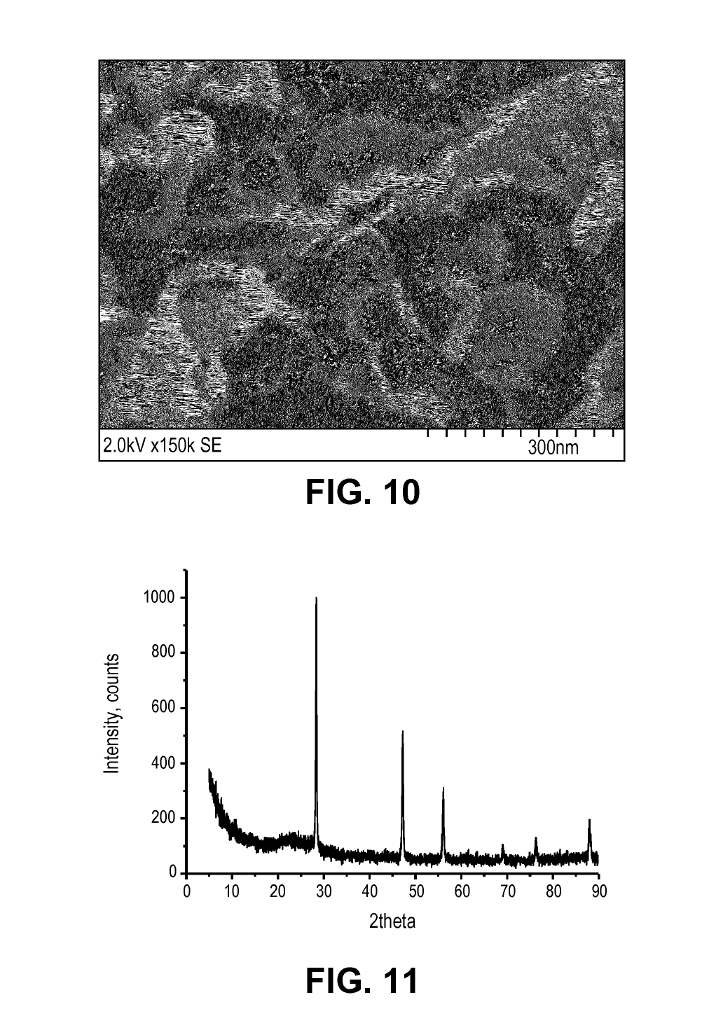

FIG. 10 is an SEM image of the surface of Si/CNT/graphene composite formed from low surface area silica.

What is claimed is:

1. A method for forming amorphous silicon material comprising:
mixing silica with a reductive metal to form a mixture;
ball milling the mixture under sufficient conditions to initiate a reaction between the silica and the reductive metal; and
heat treating the ball-milled material under sufficient conditions to produce a silicon-metal oxide composite material.

2. The method of claim 1 further comprising removing at least some of the metal oxide from the composite material.

3. The method of claim 2 wherein the step of removing at least some of the metal oxide from the composite material comprises exposing the silicon-metal oxide composite material to an acid.

4. The method of claim 1 wherein the step of heat treating is performed in an inert atmosphere.

5. The method of claim 4 wherein the metal oxide is volatile, the method further comprising altering the atmosphere to a reactive, carbon containing, atmosphere so as to produce a silicon-carbon composite material.

6. The method of claim 2 further comprising exposing the composite material to a second heat treatment step in a reactive, carbon containing, atmosphere so as to produce a silicon-carbon composite material.

7. The method of claim 6 further comprising mixing the composite material with iron nitrate prior to exposing the composite material to the second heat treatment step, so as to produce a silicon-carbon nanotube composite material.

8. The method of claim 6 further comprising mixing the composite material with iron nitrate and graphene oxide prior to exposing the composite material to the second heat treatment step, so as to produce a silicon-carbon nanotube—graphene composite material.

9. The method of claim 1 wherein the silica is selected from the group consisting of silicon oxide and silicon dioxide.

10. The method of claim 1 wherein the reductive metal is selected from the group consisting of magnesium, aluminum, calcium, sodium, potassium, and lithium.

11. The method of claim 1 wherein the silica is low surface area silica.

12. The method of claim 1 wherein the silica is high surface area silica.

13. An amorphous silicon material comprising a highly irregular external surface formed from a plurality of silicon crystallites and voids.

14. The silicon material of claim 13 wherein the voids are formed by the removal of a metal oxide from the surface of a silicon-metal oxide composite material.

15. The silicon material of claim 13 further comprising an externally inaccessible core that comprises the metal oxide.

16. The silicon material of claim 13 further comprising carbon as part of the composite material.

17. An amorphous silicon material consisting of silicon, silicon crystallites, metal oxide, carbon, and voids.

18. The amorphous silicon material of claim 17 wherein the metal oxide forms part of an inaccessible core and the external surface is formed solely from silicon and carbon.
